(19) United States
(12) Patent Application Publication
(10) Pub. No.: US 2006/0278964 A1
(43) Pub. Date: Dec. 14, 2006

(54) Plastic integrated circuit package, leadframe and method for use in making the package

(75) Inventors: Emmievel S. Anacleto, Quezon City (PH); Mark Henry S. Antiporta, Manila (PH); Fernando V. Capinig, Quezon City (PH); Mizpa B. Mijares, San Carlos City (PH)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: PSi Technologies, Inc.

(21) Appl. No.: 11/147,756

(22) Filed: Jun. 8, 2005

(51) Int. Cl. H01L 23/02

(52) U.S. Cl. 257/678

(57) ABSTRACT

A semiconductor package comprises a plurality of metal contacts, each contact having a first surface, a second surface opposite the first surface, and a locking mechanism to lock the contacts with an encapsulant material of the package. A plurality of extended metallic interconnections are provided, each having a first surface and a second surface opposite the first surface and being configured based on the configuration of interconnect regions of a semiconductor device within the package. An inverted semiconductor device is positioned on the first surfaces of the extended metallic interconnections. A plurality of uncoated metallic bumps are each electrically connected between an interconnect region of the semiconductor device and the first surface of the corresponding extended metallic interconnection. An encapsulant material covers the semiconductor device and at least a portion of each of the contacts, so that at least the second surface of the contacts is exposed. A method of making such a semiconductor package includes: providing a metal leadframe including extended metallic interconnections and contacts; providing a semiconductor device having interconnect regions each electrically connected to an uncoated metallic bump; inverting the semiconductor device and placing it on a surface of the extended metallic interconnections; electrically connecting the uncoated bumps to the extended metallic interconnections; applying and hardening an encapsulant material to cover the semiconductor device and leadframe, leaving at least a portion of each of the contacts exposed; and cutting the encapsulated leadframe and encapsulant material to sever the metal contacts.

### BACKGROUND OF THE INVENTION

The present invention relates to semiconductor packaging technology, and more particularly, to a QFN (Quad Flat No-lead) semiconductor package and a method of fabricating the same, which utilizes, but is not limited to, etching technology to produce specific routings directly to the interconnect regions of a flipped semiconductor device and uncoated metallic bumps produced, but not limited to, a wirebond interconnect process which enhances the electrical performance and other package characteristics of the packaged semiconductor device during operation.

QFN is an advanced semiconductor packaging technology, which utilizes non-protruding pins (or leads) on the bottom side of an encapsulation body, which allows the overall package to be made very compact in size. The elements of a traditional QFN package include a metal leadframe, a semiconductor device, bonding material to attach the back surface of the semiconductor device to the leadframe, bond wires which electrically connect the interconnect regions of the semiconductor device to individual tabs of the leadframe, and a hard encapsulant which covers and encloses the other components and forms the exterior of the package. Highly integrated semiconductor packages tend to be decreasingly sized and cost-effectively fabricated in compliance for use with low-profile electronic products. However, in the case of a conventional QFN semiconductor package, relatively long wire loops and occupied space above the leadframe by wires for electrically connecting the chip to the leadframe, may undesirably set certain restriction to dimensional reduction of the size of the package.

The present invention makes use of leadframe design and processing technology to produce a package configuration that accomplishes flip-chip interconnection to the leadframe with the use of uncoated metallic bumps produced, but not limited to, using wirebond interconnect process, allowing reduction of overall package dimension, while retaining the low-cost of conventional leadframe-based packaging.

### BRIEF SUMMARY OF THE INVENTION

Briefly stated, in one embodiment, the present invention comprises a package for a semiconductor device. The package comprises a plurality of metal contacts, each contact having a first surface, a second surface opposite the first surface, and means for locking the contacts with an encapsulant material of the semiconductor device package. A plurality of extended metallic interconnections are included, each having a first surface and a second surface opposite the first surface, the extended metallic interconnections being configured based on the configuration of interconnect regions of a semiconductor device within the package. An inverted semiconductor device is positioned on the first surfaces of the extended metallic interconnections. A plurality of uncoated metallic bumps are each electrically connected between an interconnect region of the semiconductor device and the first surface of the corresponding extended metallic interconnection. An encapsulant material covers the semiconductor device and underfills at least a portion of each of the contacts, so that at least the second surface of each of the contacts is exposed at a horizontal first exterior surface of the package.

In another embodiment, the present invention comprises a method of making a semiconductor package comprising the steps of: providing a thin metal leadframe including extended metallic interconnections and metal contacts; providing a semiconductor device having a plurality of interconnect regions each electrically connected to an uncoated metallic bump; inverting the semiconductor device and placing it on a surface of the extended metallic interconnections of the leadframe; electrically connecting the uncoated bumps to the extended metallic interconnections of the leadframe; applying and hardening an encapsulant material to cover the semiconductor device and leadframe, leaving at least a portion of each of the contacts exposed; and cutting the encapsulated leadframe and hardened encapsulant material to sever the metal contacts from the remainder of the leadframe.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a flow diagram of a preferred method of making a QFN package in accordance with the present invention;

FIG. 2 is a top plan view of a leadframe used for making a QFN package in accordance with a preferred embodiment of the present invention;

FIG. 3 is an enlarged cross-sectional side elevation view of a connection between an extended metallic interconnection and a tab taken along line 3-3 of FIG. 2;

FIG. 4 is an enlarged cross-sectional side elevation view of a first embodiment of a side surface contact taken along line 4-4 of FIG. 2;

FIG. 5 is an enlarged cross-sectional side elevation view of a first alternate embodiment of a side surface contact;

FIG. 6 is an enlarged cross-sectional side elevation view of a second alternate embodiment of a side surface contact;

FIG. 7 is an enlarged cross-sectional side elevation view of a third alternate embodiment of a side surface contact;

FIG. 8 is a top plan view of a semiconductor device;

FIG. 9 is an enlarged cross-sectional side elevation view of an interconnect region of the semiconductor device taken along line 9-9 of FIG. 8;

FIG. 10 is a cross-sectional side elevation view of a partially completed QFN package in accordance with the preferred embodiment of the present invention;

FIG. 11 is an enlarged view of the circled portion of the partially completed QFN package of FIG. 10;

FIG. 12 is a perspective view of a partially completed QFN package after encapsulation and including dashed lines to indicate cutting paths for a subsequent sawing step; and

FIG. 13 is a cross-sectional side elevation view of a completed QFN package in accordance with the preferred embodiment of the present invention.

### DETAILED DESCRIPTION OF THE INVENTION

The present invention is directed towards an improved plastic package for housing a semiconductor device, and a method of making such a package. The packages of the present invention are more efficiently-sized and characteristically optimized than conventional packages

In one embodiment of the assembly method for a package within the present invention, Step 1 provides a metal leadframe. The leadframe includes a rectangular frame, with a plurality of metal tabs and extended metallic interconnections. The number and location of the metal tabs and extended metallic interconnections may vary, depending on the semiconductor device design configuration. The tabs and extended metallic interconnections have peripheral side surfaces, which may include a reentrant portion(s) and asperities which enhance the connection between tabs and extended metallic interconnections to the encapsulant. The extended metallic interconnections are connected to designate tabs and are extending towards a specific area of the semiconductor device. Conversely, an extended metallic interconnection may be connected to another extended metallic interconnection if both need to be connected to the same interconnect region of the semiconductor device.

In Step 2, the interconnect regions of the semiconductor device is populated with a series of metallic bumps using, but not limited to wirebond interconnect process. Step 3 places an inverted semiconductor device on top of the leadframe and electrically connects the interconnect regions of the semiconductor device to the specific extended metallic interconnections. The conductive adhesive material enhances the connection between the metallic bumps and extended metallic interconnections. Step 4 places the leadframe on a flat surface, with the back surface of the semiconductor device facing upwards, and applies a viscous encapsulant onto the upward facing first surface of the leadframe. The encapsulant is then hardened. The encapsulant then covers part of the first surface of the semiconductor device, the second surface and side surfaces of the semiconductor device, parts of the first surface of the extended metallic interconnection, the second and side surfaces of the extended metallic interconnections, the first surface and side surfaces of the tabs and all or part of the frames of the leadframe. The lower second surface of the leadframe, including the lower second surface of the tabs, is not covered with the encapsulant.

Step 5 coats the exposed surfaces of the leadframe, including the exposed second surfaces of the tabs, with a solderable metal. Step 6 cuts the encapsulated portions of the leadframe with a saw or other shearing apparatus which either obliterates the disposable portions of the leadframe, or severs the disposable portions of the leadframe from other components of the leadframe, such as the tabs, which are to be included in the package. Step 6 also cuts the encapsulant, thereby forming the peripheral sides of the package.

A feature of the packages built by the above-described method is that the metal contacts (i.e., severed tabs of the leadframe) of the package are located at the lower first surface of the package. The first surface and side surfaces of the tabs and the entire extended metallic interconnections are internal to the package, i.e., covered with encapsulant, but the second surfaces of the tabs are not covered by the encapsulant.

In a completed package, only the encapsulant holds the extended metallic interconnections and metal contacts (i.e., severed tabs of the leadframe) to the package. The connection of the encapsulant material to the extended metallic interconnections and the contacts (i.e., severed tabs of the leadframe) is enhanced by the reentrant portion(s) and asperities of the side surfaces of the extended metallic interconnections and contacts (i.e., severed tabs of the leadframe). The reentrant portions and asperities of the side surfaces of the extended metallic interconnections and contacts (i.e., severed tabs of the leadframe) function as encapsulant fasteners or lead locks.

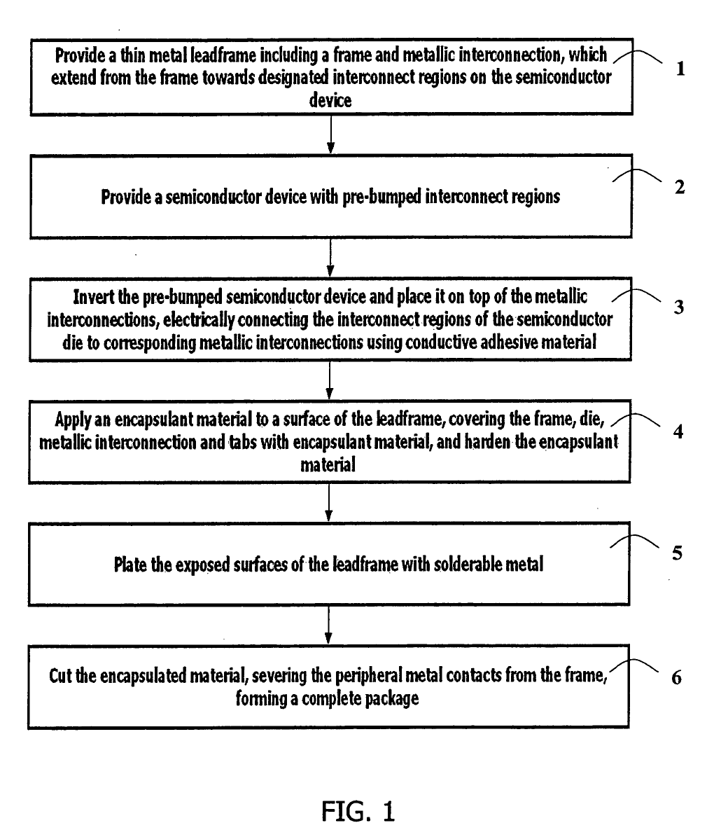

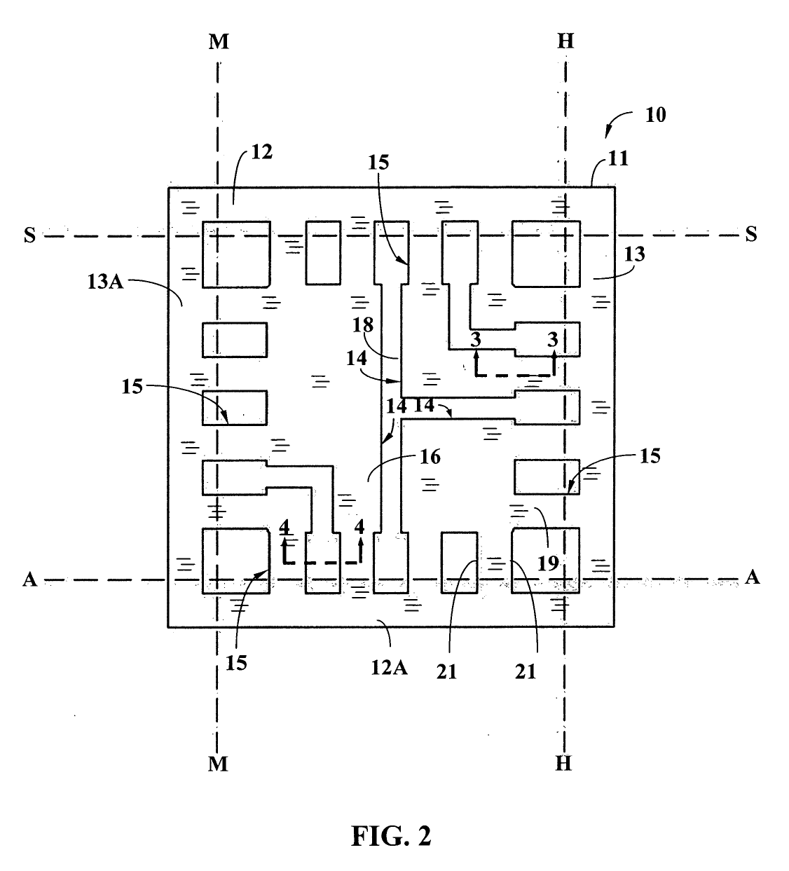

Referring to the drawings wherein the same reference numerals are used for the same elements throughout the several figures, there is shown in FIG. 1 a flow diagram of an exemplary method of assembling a QFN package in accordance with a preferred embodiment of the present invention. The first step in the method is to provide a thin metal leadframe (block 1.). FIG. 2 is a top plan view of a first embodiment of a metal leadframe 10 in accordance with the present invention. The leadframe 10 is thin and planar or substantially planar and is made of a conventional leadframe metal, dependent on the application. The leadframe 10 includes a peripheral rectangular frame 11 which is comprised of two intersecting pairs of parallel, generally rectangular frame members denoted as members 12 and 12A and 13 and 13A. Those skilled in the art will understand that the terms “rectangular” or “rectangle” as used herein includes a square, which is a rectangle with four equal sides. Preferably the leadframe 10 is formed from rolled strip metal stock by wet chemical etching or mechanical stamping using progressive dies. However, other manufacturing techniques or processes may be used if desired.

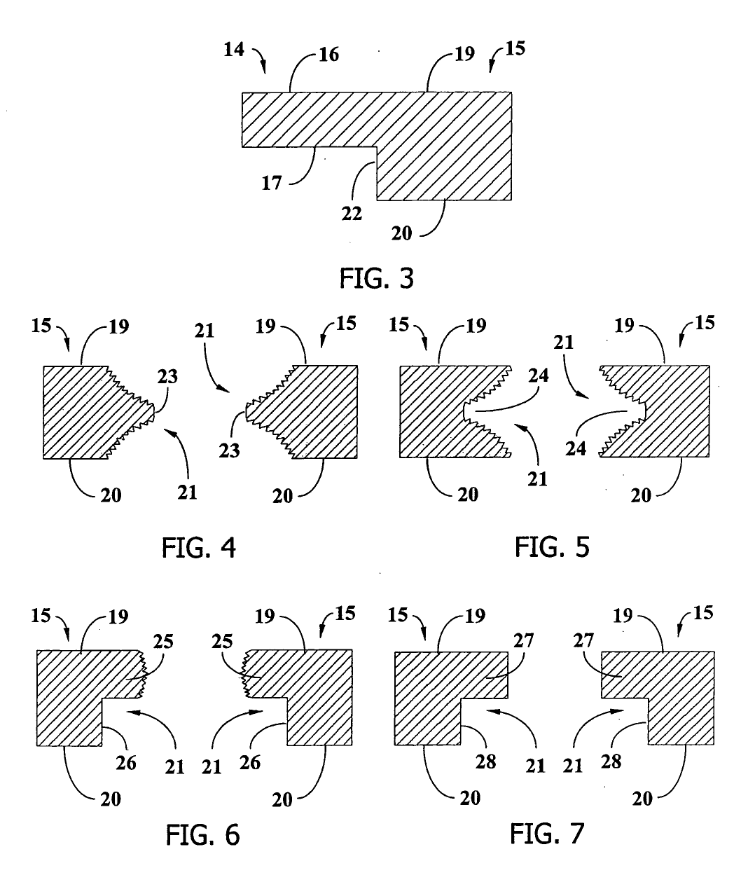

Extended metallic interconnections 14 are included within and connected to the frame 11 through a plurality of designated finger-like tabs 15. As best seen in FIG. 3, the extended metallic interconnections 14 each have a planar or substantially planar upper surface 16 and an opposite planar or substantially planar lower second surface 17. As shown in FIG. 2 the extended metallic interconnections 14 each have peripheral side surfaces 18 between the upper first surface 16 and the lower second surface 17.

Four finger-like tabs 15 are connected to each of the four frame members 12, 12A, 13 and 13A as shown in FIG. 2 which as described below provide four contacts on each of the four sides of the completed package, thus, a quad package. The number, location, and shape of the tabs 15 and the extended metallic interconnections 14 may vary for particular applications. For example, instead of having the tabs 15 on all four frame members 12,12A, 13 and 13A, the tabs 15 could be provided only on two parallel frame members, either members 13 and 13A, or 12 and 12A. This alternative embodiment results in the formation of a DFN (Dual Flat No-lead) package with contacts only on two parallel sides of the package.

Each of the tabs 15 has a planar or substantially planar upper first surface 19 and an opposite planar or substantially planar lower second surface 20 as shown in FIG. 3. Each tab 15 also has opposite peripheral side surfaces 21 extending between the upper first surface 19 and the lower second surface 20. FIG. 2 includes four dashed cut lines M-M, H-H, S-S, and A-A. The cut lines M-M, H-H, S-S, and A-A indicate the locations where the leadframe 10 is cut in Step 7 of FIG. 1 as described in greater detail below. The tabs 15 ultimately are severed from the frame members 12, 12A, 13, and 13A when the cuts are made along the cut lines, M-M, H-H, S-S, and A-A, and become the contacts of the final package.

FIG. 3 is an enlarged cross-sectional side elevation view of a portion of the leadframe 10 taken along line 3-3 of FIG. 1. In particular, FIG. 3 shows, in accordance with the present invention, the surface transition or connection between an extended metallic interconnection 14 and the related tabs 15. FIG. 3 also shows a reentrant orthogonal portion 22 beneath the extended metallic interconnection 14, adjacent to lower second surfaces 17 and 20 of the extended metallic interconnection 14 and tabs 15, respectively. Encapsulant material when applied as described below flows beneath the extended metallic interconnection 14. In a complete package, the reentrant portion 22 functions to secure each of the extended metallic interconnections 14 in its respective position. Each reentrant portion 22 also enhances the connection between the encapsulant material and the contacts of the package (i.e., severed tabs 15 as described below).

FIG. 4 is an enlarged cross-sectional side elevation view of the side surface of one of the tabs 15 of the frame 10 taken along line 4-4 of FIG. 1. As shown in FIG. 4 the side surfaces 21 of the tab 15 also have reentrant portions. In particular, the upper and lower portions of side surfaces 21 are reentrant such there is a central peak 23 which extends outwardly from side surfaces 21. Encapsulant material, when applied as described below flows into the reentrant portions of the side surfaces 21 of each of the tabs 15 so that the central peak 23 of each side surface extends into and is captured by the encapsulant material. In this manner, the reentrant portions of the side surfaces 21 of each of the tabs 15 function, in a complete package, to enhance the connection between the encapsulating material and the contacts of the package (i.e., severed tabs 15).

In addition to having reentrant portion, the side surfaces 21 of each of the tabs 15 have a roughly textured surface, which includes numerous asperities. Encapsulant material flows into the areas of the asperities to further enhance the connection between the encapsulant material and contacts of the package (i.e., the severed tabs 15).

FIG. 5 is a view similar to FIG. 4 and shows a first alternative profile for the side surfaces 21 of each of the tabs 15 of the frame 10. In the embodiment of FIG. 5, the side surfaces 21 each have a central depression 24 and a roughly textured surface, which includes numerous asperities. Encapsulant material flows into the central depression 24 and in the areas of the asperities. The reentrant portion and asperities of the side surfaces 21 of FIG. 5 function, in a completed package, to enhance the connection between the encapsulant material and the contacts of the package (i.e., the severed tabs 15).

FIG. 6 is a view similar to FIG. 4 and shows a second alternative profile for the side surfaces 21 of each of the tabs 15 of the frame 10. In the embodiment of FIG. 6, the side surfaces 21 each include a rounded lip 25 adjacent to the upper surface 19 of the tabs 15. The lip 25 has a roughly textured surface, which includes numerous asperities. The side surfaces 21 also have a reentrant orthogonal portion 26 beneath the lip 25, adjacent to the lower second surface 20 of the tabs 15. Encapsulant material flows around and beneath the lip 25 and into the area of the asperities. Like the embodiments of FIGS. 4 and 5, the reentrant portions and asperities of the side surface 21 of the tabs 15 function, in a completed package, to enhance the connection between the encapsulant material and the contacts of the package (i.e., the severed tabs 15).

FIG. 7 is a view similar to FIG. 4 and shows a third alternative profile for the side surfaces 21 of the tabs 15 of the frame 10. In this embodiment, the side surfaces 21 each include a rectangular lip 27 adjacent to the upper surface 19 of the tabs 15. The side surfaces 21 also have a reentrant orthogonal portion 28 beneath the lip 27 adjacent to the lower second surface 20 of the tabs 15. Encapsulant material flows around and beneath the lip 27. Like the embodiments of FIGS. 4-6, the reentrant portions of the side surfaces 21 of the tabs 15 of FIG. 7 function, in a completed package, to enhance the connection between the encapsulant material and the contacts of the package (i.e., severed tabs 15).

As discussed above, step 1 of the method illustrated by the flow diagram of FIG. 1 involves providing a metal leadframe 10 having features like those described above and shown in FIG. 2, FIG. 3, and either FIG. 4, 5, 6, or 7, or an equivalent thereof.

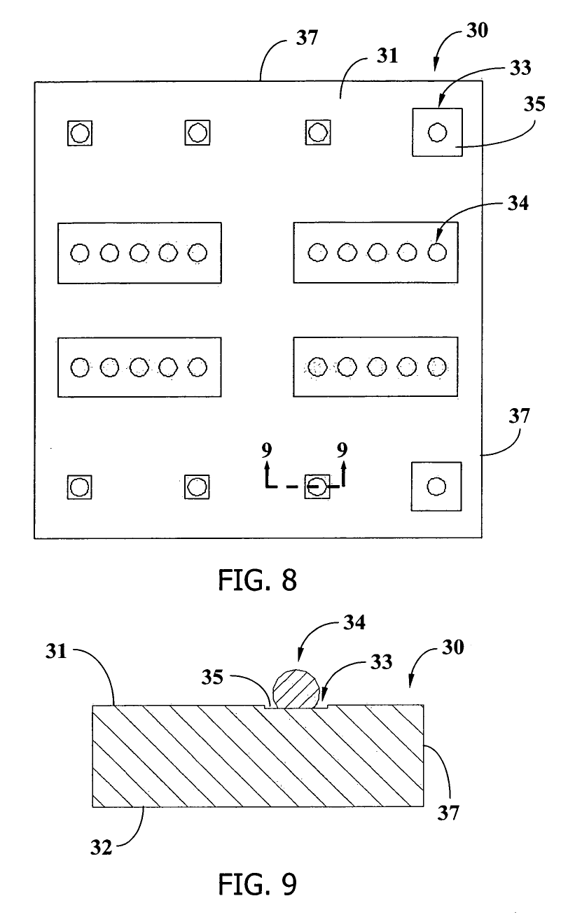

Step 2 of the method illustrated by the flow diagram of FIG. 1 involves providing a semiconductor device with pre-bumped interconnect regions. FIG. 8 is a top plan view of a first embodiment of a semiconductor device 30. The semiconductor device 30 has a planar or substantially planar upper surface 31 and, an opposite planar or substantially planar lower second surface 32 (see FIG. 9). The semiconductor device 30 is made of conventional semiconductor device material, depending on the application. Rectangular interconnect regions 33 are provided on the upper first surface 31 of semiconductor device 30. In the illustrated semiconductor device 30 there are two rows of five such rectangular interconnect regions 33 which are planar or substantially planar, and are used to electrically connect the semiconductor device 30 to external conductors.

As best shown in FIGS. 8 and 9, metallic bumps 34 are connected on the top surfaces 35 of each of the interconnect regions 33. The metallic bumps 34 are preferably made of solderable metal without a coating or a plating, such as, but not limited to, gold, aluminum, or copper, depending on the application. Other types of metallic bumps may alternatively be employed.

The shape of the semiconductor device 30 may vary depending on the particular application. The number, location, and shape of the interconnect regions 33 and the metallic bumps 34 on the semiconductor device 30 may also vary. For example, instead of having small interconnect regions 33, the semiconductor device may have a large interconnect region on its upper first surface to be able to accommodate a larger numbers of metallic bumps 34. Conventional wire bond equipment can be used for Step 2 but other equipment and/or techniques may alternatively be used. Preferable, during Step 2 and the subsequent assembly steps, ESD (electrostatic discharge) protection tools and techniques are used to protect the semiconductor device 30 from any potential damage resulting from any ESD.

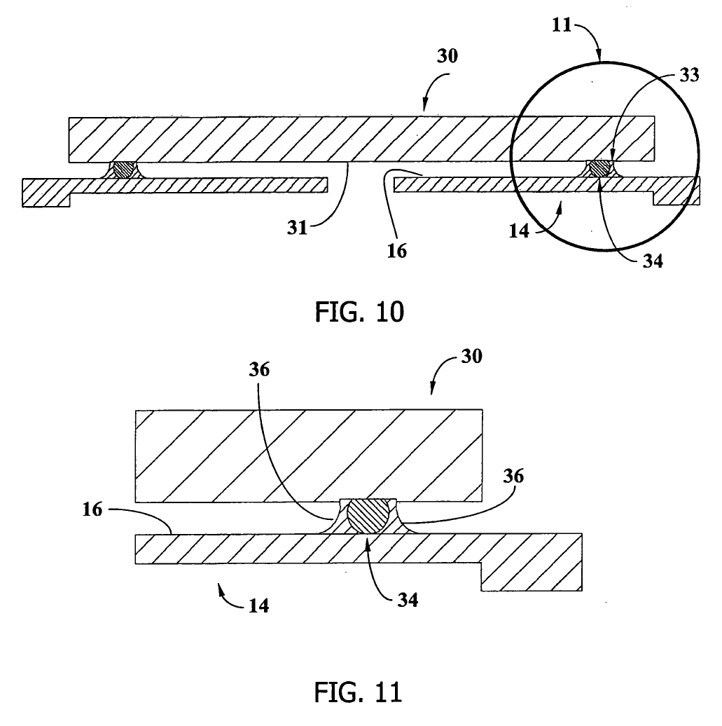

In step 3 of the present method conductive adhesive material 36 is applied on top of the upper first surface 16 of the extended metallic interconnections 14 of the leadframe 10 and, as shown in FIG. 10, the semiconductor device 30 is inverted and placed on top of the leadframe 10 such that the first surface 31 of the semiconductor device 30 faces the upper first surface 16 of the extended metallic interconnections 14 of the leadframe 10. The interconnect regions 33 of the semiconductor device 30 are also connected to the extended metallic interconnections 14 through the bumps 34. FIG. 11 is an enlarged view of the circled portion of FIG. 10 showing the bumps 34 of the semiconductor device 30 surrounded by the conductive adhesive material 36. The conductive adhesive material 36 enhances the connections between the upper first surface 16 of the extended metallic interconnections 14 and the bumps 34 of the semiconductor device 30. The interconnection of the leadframe 10 and the semiconductor device 30 can be accomplished using conventional solder dispensing equipments, pick-and-place machines and reflow ovens or other such equipment known in the art. Such equipment can also be integrated into a single system, simplifying the production process.

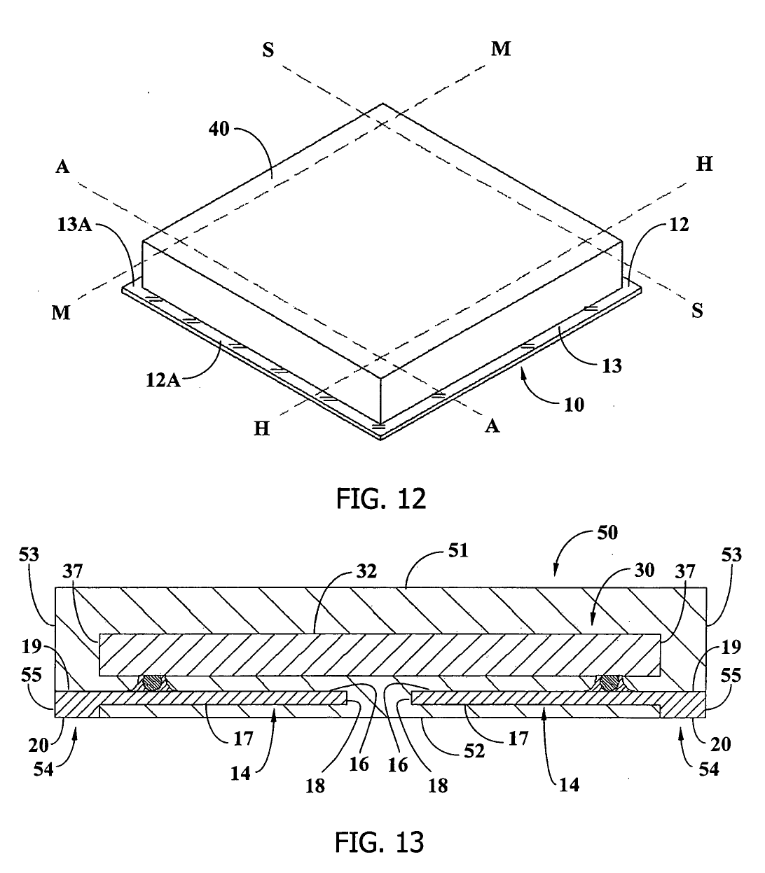

In Step 4 of the present method, the lower second surface of the leadframe 10 is placed on a flat surface, and a viscous adhesive encapsulating material 40 is applied onto the upward-facing upper first surface of the leadframe 10 as shown in FIGS. 12 and 13. The encapsulating material 40 is applied so that the encapsulating material 40 covers: the entire lower second surface 32 and the peripheral sides 37 of the semiconductor device 30; the peripheral side surfaces 18 and 21 of the extended metallic interconnections 14 and tabs 15, respectively; part of the upper first surfaces 16 and 19 of the extended metallic interconnections 14 and tabs 15, respectively; the entire lower second surfaces 17 of the extended metallic interconnections 14; part of the first surface 31 of the semiconductor device 30; part of the surface of the conductive adhesive material 36; and part or all of the width of frame members 12, 12A, 13 and 13A. The encapsulant material 40 also fills the empty spaces between the components within the leadframe 10. The encapsulant material 40 preferably does not cover the lower second surface 20 of any of the tabs 15.

The encapsulant material 40 may be applied using plastic molding methods and/or techniques well known to those skilled in the art. In one such well known method, the leadframe 10 is placed in a mold and a single block of solid molded encapsulant material 40 is formed above and on the leadframe 10, including on its side surfaces. The encapsulant material 40 can be applied using conventional techniques. Finally, the encapsulant material 40 is cured or hardened. A rectangular block of hardened encapsulant 40 covers the upper first surface of leadframe 10 as shown in FIG. 12. Although not shown in FIG. 12, the encapsulant 40 also covers the side surfaces 21 of the tabs 15, and the surfaces of the extended metallic interconnections 14. The block of encapsulant material 40 also covers a portion of the width of frame members 12, 12A, 13 and 13A. As shown in FIG. 12, the peripheral portions of the frame members 12, 12A, 13 and 13A extend outwardly beyond the encapsulant material 40 and remain exposed. Alternatively, the encapsulant material 40 could be deposited over the entire upper first surface of the leadframe 10. As a second alternative, the encapsulant material 40 could be deposited within the frame 11 so that the tabs 15 are covered, but frame members 12, 12A, 13 and 13A are not covered. The portions of the leadframe 10 which are not covered with the encapsulant material 40, include the lower second surface 20 of each of the tabs 15, which are plated using a solderable plating metal of a type well known in the art and which is compatible with printed circuit boards. For example, the exposed lower second surface 20 of each of the tabs 15 may be plated with, but not limited to, lead-tin, tin, silver, lead-tin-silver or a similar plating metal depending on the application.

In Step 6 of the present method the leadframe 10 is cut along cutting lines M-M, H-H, S-S, and A-A. The cuts may be made using a saw, shearing apparatus or any other such device or apparatus known to those skilled in the art. Referring to FIGS. 2 and 12, cutting the leadframe in this manner severs the connection between each of the tabs 15 and all of the other members of the leadframe 10, leaving all or most of each of the tabs 15 intact. Portions of the encapsulant material 40 are also cut, forming vertical external side surfaces of the package.

Finally, in Step 7, the formation of the package is completed by cutting the completed package away from the remaining disposable portions of the leadframe 10.

FIG. 13 is a cross-sectional side view of a completed exemplary package 50 made from the leadframe 10 of FIG. 2 according to the method of Steps 1-7 of FIG. 1. The package 50 has a planar or substantially planar external upper first surface 51, and an opposite planar or substantially planar external lower second surface 52. Orthogonal external package sides 53 are at the periphery of the package 50, between the upper first surface 51 and the lower second surface 52. The sides 53 were formed during Step 6 of the present method when the encapsulant material 40 and tabs 15 were cut. The lower second surface 52 of the package 50 includes a plurality of peripheral contacts 54 and the hardened encapsulant material 40. The peripheral contacts 54 are physically separated from each other by the encapsulant material 40. The contacts 54 are vestiges of the leadframe 10 and were formed when the connections between the tabs 15 and the frame members 12, 12A, 13 and 13A were severed during the cutting step (Step 6)

As shown in FIG. 13, the inverted semiconductor device 30 is on and attached to the upper first surface 16 of the extended metallic interconnections 14 and the lower second surface 32 and peripheral side surfaces 37 of the semiconductor device 30 are covered by the encapsulant material 40. The lower second surface 17 and side surfaces 18 of the extended metallic interconnections 14 are also covered by encapsulant material 40.

Only two contacts 54 are shown in the package 50 but since the package 50 was constructed from the leadframe 10 of FIG. 2, it should be understood that package 50 has a set of four contacts 54 on each of the sides of the package 50. In alternative embodiments, the package 50 could be formed with different numbers or arrangements of contacts 54, depending on the application. Each contact 54 has a substantially rectangular perimeter and is located at the lower second surface 52 of the package 50. Each contact 54 includes a planar or substantially planar upper first surface 19, an opposite planar or substantially planar lower second surface 20 and, although not shown in FIG. 13, side surfaces 21. The second surface 20 of each of the contacts 54 is in the same plane as the second surface 52 of the package 50. The first surface 19 and, though not shown in FIG. 13, the side surfaces 21 of contacts 54 are covered with the encapsulant material 40. The second surface 20 and portions or the entire external side surface 55 of the contacts 54 are not covered with the encapsulant material 40. The orthogonal external side surfaces 55 of the contacts 54 were formed during Step 6 when the connection between the tabs 15 and the frame members 12, 12A, 13 and 13A were severed. Accordingly, the external side surface 55 of the contacts 54 has a vertical profile, which is in the same plane as the corresponding vertical side 53 of package 50. Although not shown in FIG. 13, the internal side surfaces 21 of each contact 54 have reentrant portions and in some cases asperities, as exemplified by FIGS. 4-7. Both the reentrant portion(s) and the asperities of contacts 54 enhance the connection between the contacts 54 and the encapsulant material 40 of the package 50. The perimeter of the contacts 54 need not be substantially rectangular in shape. For example, if the tabs 15 of the leadframe 10 had a circular perimeter, then the contacts 54 would have a largely circular perimeter with a rectilinear portion.

The above description of embodiments of this invention is intended to be illustrative only and not limiting. Other embodiments of this invention will be obvious to those skilled in the art in view of the above disclosure. It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A package for a semiconductor device comprising:
a plurality of metal contacts, each of the contacts having a first surface, a second surface opposite the first surface, and means for locking the contacts to encapsulant material of the semiconductor device package;
a plurality of extended metallic interconnections, each having a first surface and a second surface opposite the first surface, the extended metallic interconnections being patterned based on the configuration of interconnect regions of a semiconductor device within the package;
an inverted semiconductor device positioned on the first surface of the extended metallic interconnections;
a plurality of metallic bumps, each electrically connected between an interconnect region of the semiconductor device and the first surface of the corresponding extended metallic interconnection; and
an encapsulant material covering the semiconductor device and under filling at least a portion of each of the contacts, wherein at least the second surface of the contacts are exposed at a horizontal first exterior surface of the package.

2. The package of claim 1, wherein said means for locking includes asperities, said asperities being covered by the encapsulant material.

3. The package of claim 1, wherein the second surface of each of the extended metallic interconnections is exposed at the first exterior surface of the package.

4. The package of claim 3, wherein each of the extended metallic interconnections includes means for locking the extended metallic interconnections to the encapsulant material.

5. The package of claim 4, wherein said means for locking includes asperities, said asperities being covered by the encapsulant material.

6. The package of claim 1, wherein the second surface of each of the extended metallic interconnections is covered with the encapsulant material.

7. The package of claim 1, wherein the first surface of each of the extended metallic interconnections is in a horizontal plane with the first surface of the contacts.

8. The package of claim 1, wherein the first surface of each of the extended metallic interconnections is not in a horizontal plane with the first surface of the contacts.

9. The package of claim 1, wherein the package includes orthogonal exterior side surfaces adjacent to the first exterior surface of the package, and the second end of each contact is exposed in a common plane with one of the exterior side surfaces of the package.

10. The package of claim 1, wherein the uncoated metallic bumps are secured to the first surface of the extended metallic interconnections using a conductive adhesive material.

11. A method of making a semiconductor package comprising the steps of:
providing a thin metal leadframe including a plurality of interconnected frame members, each having metal tabs and extended metallic interconnections;
providing a plurality of semiconductor devices, each having a plurality of interconnect regions with uncoated metallic bumps;
placing an inverted semiconductor device on top of the first surface of the extended metallic interconnections on each of the frame members, electrically connecting the uncoated metallic bumps to the extended metallic interconnections;
applying and hardening an encapsulant material to cover the semiconductor device and leadframe, leaving at least a portion of the metal tabs exposed;
plating the exposed surfaces of the leadframe with solderable metal; and
cutting the encapsulated leadframe and hardened encapsulant material, severing the metal tabs from their respective frame members, forming the metal contacts, and forming a plurality of completed packages.

12. The method of claim 11, wherein the bumps are securely connected to the extended metallic interconnections using a conductive adhesive material.
